(19) United States
(12) Patent Application Publication
(10) Pub. No.: US 2009/0142896 A1
(43) Pub. Date: Jun. 4, 2009

(54) METHOD FOR MANUFACTURING SEMICONDUCTOR DEVICE

(76) Inventors: Kun-Hyuk Lee, Dobong-gu (KR); Sung-Kun Park, Cheongju-si (KR)

Correspondence Address: SHERR & VAUGHN, PLLC, 620 HERNDON PARKWAY, SUITE 200, HERNDON, VA, 20170, US

(21) Appl. No.: 12/326,899

(22) Filed: Dec. 3, 2008

(30) Foreign Application Priority Data
Dec. 4, 2007 (KR) 10-2007-0124922

(51) Int. Cl. H01L 21/8234

(52) U.S. Cl. 438/275; 257/E21.616

(57) ABSTRACT

A method for manufacturing a semiconductor device includes providing a semiconductor substrate having first and second low voltage transistor regions and first and second high voltage transistor regions. A dielectric layer is formed over the semiconductor substrate-in the low and high voltage transistor. Gates are formed over the dielectric layer in the low and high voltage regions. Lightly doped drains are formed in the first low-voltage transistor region and the first high-voltage transistor region by performing an ion implantation process on the semiconductor substrate using a first gate in the first low-voltage transistor region and a third gate in the first high-voltage transistor region as ion implantation masks and the dielectric layer as a buffer.

The present application claims priority under 35 U.S.C. §119 to Korean Patent Application No. 10-2007-0124922 (filed on Dec. 4, 2006), which is hereby incorporated by reference in its entirety.

### BACKGROUND

In fabrication of semiconductor devices, two or more Metal Oxide Semiconductor (MOS) transistors having different operating voltages may be produced according to uses or purposes of semiconductor devices. When it is desired to produce two types of MOS transistors having different operating voltages, different thicknesses of gate oxide layers must be formed in consideration of a difference in use voltages therebetween. A gate oxide layer of a transistor having a higher operating voltage must be thicker than a gate oxide layer of a transistor having a lower operating voltage. After forming gates on and/or over the gate oxide layers, a process for forming a Lightly Doped Drain (LDD) is performed.

The following description is limited to the case wherein two different operating voltages are employed. FIGS. 1A to 1C are process sectional views illustrating a method for manufacturing a semiconductor device that includes an LDD. In FIGS. 1A to 1C, the left region represents a low-voltage region and the right region represents a high-voltage region.

FIG. 1A illustrates a state prior to performing an LDD forming process. Referring to FIG. 1A, when gate oxide layers 104A, 104B are formed, respectively, on and/or over a silicon substrate 100A of a low-voltage region and a silicon substrate 100B of a high-voltage region and in turn, gates 106A, 106B are formed on and/or over the respective gate oxide layers 104A, 104B, residual oxide layers 102A, 102B are left on and/or over the silicon substrates 100A, 100B. To form LDDs for a low-voltage PMOS, a low-voltage NMOS, a high-voltage PMOS and a high-voltage NMOS, a photolithography process must be performed four times by use of four masks. More specifically, as shown in FIG. 1B, in a state where the low-voltage region is covered with a photoresist pattern 112, ion implantation 108 is performed to form an-LDD 110 only in the high-voltage region. Contrary to FIG. 1B, as shown in FIG. 1C, in a state where the high-voltage region is covered with a photoresist pattern 114, ion implantation 120 is performed to form an LDD 116 only in the low-voltage region.

As can be appreciated from FIGS. 1A to 1C illustrating a process for forming LDDs for NMOS (or PMOS) high-voltage and low-voltage regions, forming all LDDs for NMOS and PMOS high-voltage and low-voltage regions requires performing a photolithography process a total of four times. In consideration of a photolithography process being a high-cost process in fabrication of a semiconductor device, the above-described LDD forming process problematically increases overall manufacturing costs.

### SUMMARY

Embodiments relate to a method for manufacturing a semiconductor device forming LDDs for transistors with different operating voltages formed by a reduced number of processes using a reduced number of masks.

Embodiments relate to a method for manufacturing a semiconductor device including a plurality of transistors of different operating voltages, the method may include at least one of the following: forming a dielectric layer on and/or over a semiconductor substrate, the dielectric layer having different operating voltage regions with different thicknesses; forming gates on and/or over the dielectric layer on a transistor-by-transistor basis; forming a photo-mask pattern to expose first conductive transistors while covering second conductive transistors, regardless of different operating voltages of the transistors; and forming Lightly Doped Drains (LDDs) for the exposed first conductive transistors by performing ion implantation on the semiconductor substrate using the gates as an ion implantation mask and the dielectric layer as a buffer.

Embodiments relate to a method for manufacturing a semiconductor device including first high-voltage and low-voltage transistor regions for first conductive transistors, and second high-voltage and low-voltage transistor regions for second conductive transistors, the method may include at least one of the following: forming a dielectric layer on and/or over a semiconductor substrate, the dielectric layer having different operating voltage regions of different thicknesses; forming gates on and/or over the dielectric layer on a per transistor region basis; forming a photo-mask pattern to expose the first high-voltage and low-voltage regions while covering the second high-voltage and low-voltage transistor regions; and forming Lightly Doped Drains (LDDs) for the exposed first high-voltage and low-voltage transistor regions by performing ion implantation on the semiconductor substrate using the gates as an ion implantation mask and the dielectric layer as a buffer.

Embodiments relate to a method that may include at least one of the following: providing a semiconductor substrate having a first and second low voltage transistor regions and a first and second high voltage transistor regions; and then forming a dielectric layer over the semiconductor substrate including a first dielectric layer portion formed in the low voltage transistor regions and a second dielectric layer portion formed in the high voltage transistor regions, wherein the a first dielectric layer portion has a different thickness than the second dielectric layer portion; and then forming gates over the dielectric layer including a first gate in the first low-voltage transistor region, a second gate in the second low-voltage transistor region, a third gate in the first high-voltage transistor region and a fourth gate in the second high-voltage transistor region; and then forming a photo-mask pattern to expose the first gate in the first low-voltage transistor region and the third gate in the first high-voltage transistor region while covering the second gate in the second low-voltage transistor region and the fourth gate in the second low-voltage transistor region; and then forming lightly doped drains in the first low-voltage transistor region and the first high-voltage transistor region by performing an ion implantation process on the semiconductor substrate using the first gate in the first low-voltage transistor region and the third gate in the first high-voltage transistor region as ion implantation masks and the dielectric layer as a buffer.

Embodiments relate to a method that may include at least one of the following: providing a semiconductor substrate having first and second low voltage transistor regions and first and second high voltage transistor regions; and then forming a dielectric layer over the semiconductor substrate including a first dielectric layer portion formed in the low voltage transistor regions and a second dielectric layer portion formed in the high voltage transistor regions; and then forming gates over the dielectric layer including a first gate in the first low-voltage transistor region, a second gate in the second low-voltage transistor region, a third gate in the first high-voltage transistor region and a fourth gate in the second high-voltage transistor region; and then forming a photo-mask pattern to expose the first gate in the first low-voltage transistor region and the third gate in the first high-voltage transistor region while covering the second gate in the second low-voltage transistor region and the fourth gate in the second low-voltage transistor region; and then forming lightly doped drains in the first low-voltage transistor region and the first high-voltage transistor region by performing an ion implantation process on the semiconductor substrate using the first gate in the first low-voltage transistor region and the third gate in the first high-voltage transistor region as ion implantation masks and the dielectric layer as a buffer. In accordance with embodiments, the first low voltage transistor region and the first high voltage transistor region have first conductive-type transistors and the second low voltage transistor region and the second high voltage transistor region have second conductive-type transistors.

### DRAWINGS

FIGS. 1A to 1C illustrate a method for manufacturing a semiconductor device having an LDD.

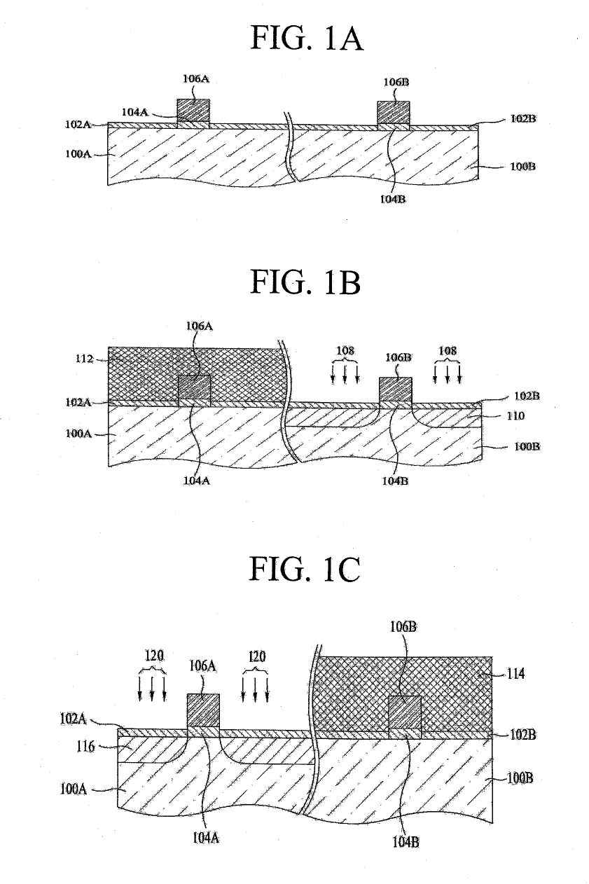

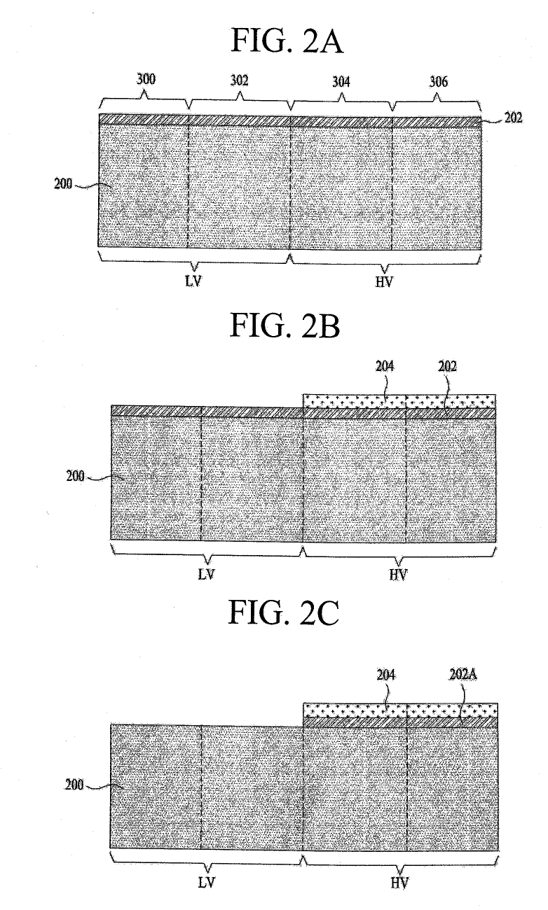

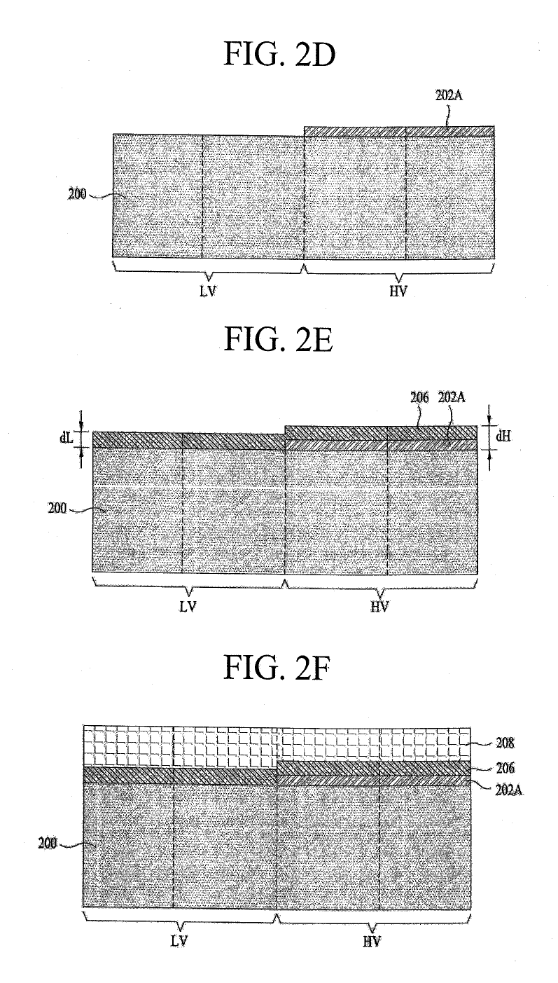

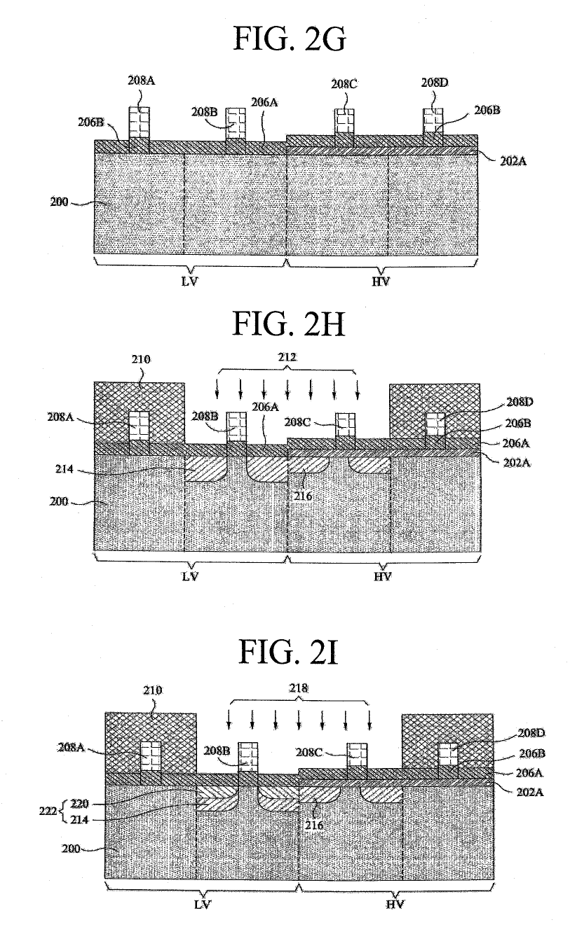

Example FIGS. 2A to 2I illustrate a method for manufacturing a semiconductor device in accordance with embodiments.

### DESCRIPTION

Example FIGS. 2A to 2I are process sectional views illustrating a method for manufacturing a semiconductor device in accordance with embodiments.

A semiconductor device, manufactured in accordance with embodiments, may include a plurality of transistors having different operating voltages from one another. Here, the transistors may be MOS transistors. For example, the semiconductor device may include at least one low-voltage transistor having a low operating voltage and at least one high-voltage transistor having a high operating voltage. Additionally, the semiconductor device may include at least one medium-voltage transistor having a medium operating voltage between the low operating voltage and the high operating voltage.

In the manufacture of the semiconductor device, first, a dielectric layer is formed on and/or over a semiconductor substrate having different operating voltage regions with different thicknesses. The dielectric layer is formed after a gate dielectric layer between the semiconductor substrate and gates of transistors. The greater the operating voltage of the transistor, the thicker the dielectric layer. For example, the dielectric layer of the high-voltage transistor is thicker than the dielectric layer of the low-voltage transistor, and the dielectric layer of the medium-voltage transistor is thinner than the dielectric layer of the high-voltage transistor, but is thicker than the dielectric layer of the low-voltage transistor.

Various methods may be used such that thicknesses of dielectric layers of transistors differ according to the magnitude of an operating voltage. One method will be described hereinafter with reference to example FIGS. 2A to 2E. Here, although only a single low-voltage transistor and a single high-voltage transistor are illustrated to assist the understanding of embodiments, it will be appreciated that embodiments are equally applicable to the case wherein at least one medium-voltage transistor and a plurality of low-voltage and high-voltage transistors are employed.

Referring to example FIG. 2A, a first dielectric layer 202 is formed on and/or over a semiconductor substrate 200 having a low voltage region LV and a high voltage region HV. The first dielectric layer 202 may be an oxide layer. Referring to example FIG. 2B, a photoresist (PR) pattern 204 is formed on and/or over a portion of the first dielectric layer 202 formed in the high-voltage region HV where a high-voltage transistor will be formed while exposing a portion of the first dielectric layer 202 formed in the low-voltage LV region where a transistor will be formed.

Referring to example FIG. 2C, the first dielectric layer 202 formed in the exposed low-voltage region LV is etched using the PR pattern 204 as an etching mask. Next, as shown in example FIG. 2D, once the PR pattern 204 is removed, the first dielectric layer 202A remains only in the high-voltage region HV. Referring to example FIG. 2E, a second dielectric layer 206 is formed on and/or over the entire surface of the semiconductor substrate 200 in the low-voltage region LV and the high-voltage region HV including the first dielectric layer 202A. Accordingly, a combined thickness dH of the first dielectric layer 202A and the second dielectric layer 206 in the high-voltage region HV may be thicker than a thickness dL of the second dielectric layer 206 in the low-voltage region LV.

Next, gates are formed on and/or over the second dielectric layer 206 on a transistor-by-transistor basis. For example, as shown in example FIG. 2F, poly-silicon layer 208 is deposited on and/or over the entire upper surface of the second dielectric layer 206. As shown in example FIG. 2G, the poly-silicon layer 208 is then patterned to form gates 208A, 208B, 208C and 208D on a transistor-by-transistor basis. In this case, when patterning the poly-silicon 208 to form the gates 208A, 208B, 208C and 208D as shown in example FIG. 2G, the second dielectric layer 206 may be partially etched at opposite sides of the respective gates 208A, 208B, 208C and 208D. Meaning, the thickness of a first portion of the second dielectric layer 206B present below the gates 208A, 208B, 208C and 208D may be equal to or thicker than the thickness of a second portion of the second dielectric layer 206A present at opposite sides of the gates 208A, 208B, 208C and 208D. After forming the gates 208A, 208B, 208C and 208D and the dielectric layers 202A and 206A, a photo-mask pattern is formed to expose first conductive transistors while covering second conductive transistors, regardless of different operating voltages of the transistors.

More specifically, to assist the understanding of embodiments, the low-voltage region LV includes a first low-voltage transistor region 302 and a second low-voltage transistor region 300, and the high-voltage region HV includes a first high-voltage transistor region 304 and a second high-voltage transistor region 306. Here, a first conductive low-voltage transistor is formed in the first low-voltage transistor region 302, and a second conductive low-voltage transistor is formed in the second low-voltage transistor region 300. Also, a first conductive high-voltage transistor is formed in the first high-voltage transistor region 304, and a second conductive high-voltage transistor is formed in the second high-voltage transistor region 306. Of course, embodiments are not limited thereto, and there may be provided a greater number of first conductive low-voltage and high-voltage transistors and second conductive low-voltage and high-voltage transistors than those shown in example FIGS. 2A to 2I. The first conductive type may be a P-type and the second conductive type may be an N-type, or vice versa. Hereinafter, a method for manufacturing the semiconductor device in accordance with embodiments will be described with reference to example FIGS. 2H and 2I under an assumption of the above description.

Ion implantations 212 and 218 are performed on the semiconductor substrate 200 by use of the gates 208B and 208C as an ion implantation mask and the dielectric layers 206A and 202A as a buffer, so as to form an LDD 216 in the exposed first high-voltage transistor region 304 and an LDD 222 in the exposed first low-voltage transistor region 302. It will be appreciated that the dielectric layer 206A, which remains after the poly-silicon 208 is etched to form the gates 208A to 208D, is used as a buffer for use in the ion implantations 212 and 218. More specifically, referring to example FIG. 2H, a photo-mask pattern 210 is formed to expose the first high-voltage transistor region 304 and first low-voltage transistor region 203 while covering the second high-voltage transistor region 306 and second low-voltage transistor region 300. Thereafter, the primary ion implantation 212 is performed so as to form the LDD 216 in the exposed first high-voltage transistor region 304. The primary ion implantation 212 is performed on the basis of the formation of the LDD 216. That is, the ion implantation 212 is performed on the basis of an ion implantation energy and dopant density suitable for the formation of the LDD 216. Accordingly, with the primary ion implantation 212, the LDD 216 can be completely formed in the first high-voltage transistor region 304 and an LDD 214 can be provisionally formed in the first low-voltage transistor region 302. For this, the ion implantation energy is sufficiently determined to transmit through both the buffers 206A and 202A.

Since the primary ion implantation 212 is performed in consideration of electrical characteristics of a first conductive high-voltage transistor, the provisionally formed LDD 214 does not meet electrical characteristics of a first conductive low-voltage transistor. Accordingly, as shown in example FIG. 2I, the secondary ion implantation 218 is performed to compensate for characteristics deficient in the first conductive low-voltage transistor, completing the LDD 222. The secondary ion implantation energy is determined to transmit through only the buffer dielectric layer 206A in the first low-voltage transistor region 302 while not transmitting through the buffer dielectric layers 202A and 206A in the first high-voltage transistor region 304. Accordingly, the LDD 216 in the first high-voltage transistor region 304 is not affected by the secondary ion implantation 218. As described above, in consideration of different electrical characteristics of low-voltage and high-voltage transistors although the transistors are of the same conductive type, the present invention proposes that ion implantation to form LDDs for the high-voltage and low-voltage transistors be performed two times.

In the primary and secondary ion implantations 212 and 218, dopant density and ion implantation energy can be determined based on simulation results. For example, the thickness dL of the buffer dielectric layer 206A may be set in a range between approximately 50 to 70 Å, the thickness dH of the buffer dielectric layers 202A and 206A may be set in a range between approximately 100 to 150 Å, the energy E1 of the ion implantation 212 may be set in a range between approximately 40 to 60 KeV, the energy E2 of the ion implantation 218 may be set in a range between approximately 5 to 10 KeV, the thickness L1 of the LDD 214 may be set in a range between approximately 500 to 900 Å, and the thickness L2 of an LDD 220 formed by the secondary ion implantation 218 may be set in a range between approximately 100 to 200 Å.

In accordance with embodiments, when it is desired that the LDD 216 in the first high-voltage transistor region 304 have a higher dopant density than the LDD 222 in the first low-voltage transistor region 302, a dopant used in the primary ion implantation 212 and a dopant used in the secondary ion implantation 218 may be elements of different groups of the periodic table. For example, in the case where the primary ion implantation 212 is performed using a group III element and it is desired that the LDD 216 in the first high-voltage transistor region 304 have a higher dopant density than the LDD 222 in the first low-voltage transistor region 302, the secondary ion implantation 218 is preferably performed using a group V element to lower the density of the LDD 214 because the density of the LDD 214 that is provisionally formed by the primary ion implantation 212 is higher than a target density.

Alternatively, in accordance with embodiments, when it is desired that the LDD 216 in the first high-voltage transistor region 304 have a lower dopant density than the LDD 222 in the first low-voltage transistor region 302, a dopant used in the primary ion implantation 212 and a dopant used in the secondary ion implantation 218 may be elements of the same group of the periodic table. For example, in the case where the primary ion implantation 212 is performed using a group III element and it is desired that the LDD 216 in the first high-voltage transistor region 304 have a lower dopant density than the LDD 222 in the first low-voltage transistor region 302, the secondary ion implantation 218 is preferably performed using a group III element to raise the density of the LDD 214 up to a target density because the density of the LDD 214 that is provisionally formed by the primary ion implantation 212 is lower than the target density.

In conclusion, in other methods, a photolithography process must be performed four times using four photo-masks to form LDDs for a PMOS high-voltage transistor, NMOS high-voltage transistor, PMOS low-voltage transistor and NMOS low-voltage transistor. However, in accordance with embodiments, LDDs for PMOS high-voltage and low-voltage transistors can be formed using a single photo-mask, and LDDs for NMOS high-voltage and low-voltage transistors can be formed using a single photo-mask. Accordingly, embodiments can reduce the number of photo-masks for formation of LDDs as compared to other methods, and consequently, reduce the implementation number of photolithography processes.

Alternatively, similar to the case shown in example FIGS. 2A to 2I, after covering the first low-voltage transistor region 302 and first high-voltage transistor region 304 with another photo-mask pattern, ion implantation is performed two times to form LDDs in the second low-voltage transistor region 300 and second high-voltage transistor region 306.

Although the above description of example FIGS. 2A to 2I is limited to the low-voltage and high-voltage regions, embodiments are not limited thereto and is applicable to the case where a medium-voltage region is further provided. In this case, it will be clearly understood that the number of photo-masks and the implementation number of photolithography processes are further reduced.

As apparent from the above description, a method for manufacturing a semiconductor device in accordance with embodiments, with relation to transistors which are of the same conductive type, but have different operating voltages, LDDs for the transistors can be formed using the same photo-mask. Specifically, LDDs for PMOS high-voltage and low-voltage transistors can be formed using the same photo-mask, and LDDs for NMOS high-voltage and low-voltage transistors can be formed using the same photo-mask. As a result, LDDs for all transistors can be formed with a reduced number of photo-masks and photolithography processes. This has the effect of reducing a production price of a semiconductor device and reducing the overall manufacturing time with a simplified manufacturing process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate having first and second low voltage transistor regions and first and second high voltage transistor regions; and then
forming a dielectric layer over the semiconductor substrate including a first dielectric layer portion formed in the low voltage transistor regions and a second dielectric layer portion formed in the high voltage transistor regions, wherein the a first dielectric layer portion has a different thickness than the second dielectric layer portion; and then
forming gates over the dielectric layer including a first gate in the first low-voltage transistor region, a second gate in the second low-voltage transistor region, a third gate in the first high-voltage transistor region and a fourth gate in the second high-voltage transistor region; and then
forming a photo-mask pattern to expose the first gate in the first low-voltage transistor region and the third gate in the first high-voltage transistor region while covering the second gate in the second low-voltage transistor region and the fourth gate in the second low-voltage transistor region; and then
forming lightly doped drains in the first low-voltage transistor region and the first high-voltage transistor region by performing an ion implantation process on the semiconductor substrate using the first gate in the first low-voltage transistor region and the third gate in the first high-voltage transistor region as ion implantation masks and the dielectric layer as a buffer.

2. The method of claim 1, wherein forming the lightly doped drains comprises:
performing a primary ion implantation process to form the lightly doped drain in the first high-voltage transistor region; and then
performing a secondary ion implantation to form the lightly doped drain in the first low-voltage transistor region.

3. The method of claim 2, wherein the secondary ion implantation is performed only through the dielectric layer of the first low-voltage transistor.

4. The method of claim 2, wherein a dopant used in the primary ion implantation and a dopant used in the secondary ion implantation are elements of different groups.

5. The method of claim 2, wherein a dopant used in the primary ion implantation and a dopant used in the secondary ion implantation are elements of the same group.

6. The method of claim 1, wherein forming the gates over the dielectric layer comprises:
depositing a poly-silicon layer over the entire upper surface of the dielectric layer; and then
patterning the poly-silicon layer.

7. The method of claim 6, wherein a portion of the dielectric layer is etched during the patterning of the poly-silicon layer and the remaining portion of the dielectric layer serves as the buffer during forming the lightly doped drains.

8. The method of claim 1, wherein forming the dielectric layer comprises:
forming a first dielectric layer over the semiconductor substrate; and then
forming a photoresist pattern to expose a portion of the first dielectric layer in the low-voltage transistor regions while covering a portion of the first dielectric layer in the high-voltage transistor regions; and then
etching the exposed portion of the first dielectric layer using the photoresist pattern as an etching mask; and then
removing the photoresist pattern; and then
forming a second dielectric layer over the entire surface of the semiconductor substrate including the first dielectric layer.

9. A method comprising:
providing a semiconductor substrate having first and second low voltage transistor regions and first and second high voltage transistor regions; and then
forming a dielectric layer over the semiconductor substrate including a first dielectric layer portion formed in the low voltage transistor regions and a second dielectric layer portion formed in the high voltage transistor regions; and then
forming gates over the dielectric layer including a first gate in the first low-voltage transistor region, a second gate in the second low-voltage transistor region, a third gate in the first high-voltage transistor region and a fourth gate in the second high-voltage transistor region; and then
forming a photo-mask pattern to expose the first gate in the first low-voltage transistor region and the third gate in the first high-voltage transistor region while covering the second gate in the second low-voltage transistor region and the fourth gate in the second low-voltage transistor region; and then
forming lightly doped drains in the first low-voltage transistor region and the first high-voltage transistor region by performing an ion implantation process on the semiconductor substrate using the first gate in the first low-voltage transistor region and the third gate in the first high-voltage transistor region as ion implantation masks and the dielectric layer as a buffer,
wherein the first low voltage transistor region and the first high voltage transistor region have first conductive-type transistors and the second low voltage transistor region and the second high voltage transistor region have second conductive-type transistors.

10. The method of claim 9, wherein the first conductive type is a P-type.

11. The method of claim 9, wherein the second conductive type is an N-type.

12. The method of claim 9, wherein the first conductive type is a P-type and the second conductive type is an N-type.

13. The method of claim 9, wherein the first conductive type is an N-type.

14. The method of claim 9, wherein the second conductive type is a P-type.

15. The method of claim 9, wherein the first conductive type is an N-type and the second conductive type is a P-type.

16. The method of claim 9, wherein forming the lightly doped drains comprises:
performing a primary ion implantation process to form the lightly doped drain in the first high-voltage transistor region; and then
performing a secondary ion implantation to form the lightly doped drain in the first low-voltage transistor region,
wherein the lightly doped drain in the first low-voltage transistor region is partially formed during formation of the lightly doped drain in the first high-voltage transistor region.

17. The method of claim 9, wherein the thickness of the dielectric layer in the high-voltage transistor regions is larger than the thickness of the dielectric layer in the low-voltage transistor regions.

18. The method of claim 9, wherein forming the dielectric layer comprises:
forming a first dielectric layer over the semiconductor substrate; and then
forming a photoresist pattern to expose a portion of the first dielectric layer in the low-voltage transistor regions while covering a portion of the first dielectric layer in the high-voltage transistor regions; and then
etching the exposed portion of the first dielectric layer using the photoresist pattern as an etching mask; and then
removing the photoresist pattern; and then
forming a second dielectric layer over the entire surface of the semiconductor substrate including the first dielectric layer.

19. The method of claim 9, wherein a dopant used in the primary ion implantation and a dopant used in the secondary ion implantation are elements of different groups.

20. The method of claim 9, wherein a dopant used in the primary ion implantation and a dopant used in the secondary ion implantation are elements of the same group.
